(19) United States
(12) Patent Application Publication
(10) Pub. No.: US 2026/0150593 A1
(43) Pub. Date: May 28, 2026

(54) SEMICONDUCTOR DEVICE AND METHODS FOR MANUFACTURING AND INSPECTING THE SAME

(71) Applicant: HIGHLIGHT TECH CORP., Tainan City (TW)

(72) Inventors: CHWUNG-SHAN KOU, Tainan City (TW); WEN-YUNG YEH, Tainan City (TW); CHANG-YING CHEN, Tainan City (TW)

(73) Assignee: HIGHLIGHT TECH CORP., Tainan City (TW)

(21) Appl. No.: 19/366,039

(22) Filed: Oct. 22, 2025

Related U.S. Application Data
(60) Provisional application No. 63/712,155, filed on Oct. 25, 2024.
(60) Provisional application No. 63/810,435, filed on May 22, 2025.
(60) Provisional application No. 63/860,750, filed on Aug. 9, 2025.
(60) Provisional application No. 63/878,302, filed on Sep. 9, 2025.

(30) Foreign Application Priority Data
Oct. 22, 2025 (TW) 114140823

(51) Int. Cl. H10P 14/20; H10P 34/42; H10P 72/30; H10P 74/20; H10P 95/00; H10P 95/60; H10P 95/80

(52) U.S. Cl. CPC H10P 14/2924; H10P 14/36; H10P 34/422; H10P 72/32; H10P 74/203; H10P 95/02; H10P 95/60; H10P 95/80

(57) ABSTRACT

Disclosed are a semiconductor device and methods for manufacturing and inspecting the same. The manufacturing method comprises the steps of: providing at least one substrate; and performing a forming step for forming at least one microstructure on the substrate by utilizing a processing technique selected from a group consisting of a laser processing technique, a microwave processing technique, a radio frequency processing technique, an electrical discharge machining technique, a wet chemical processing technique, a mechanical processing technique, a plasma source processing technique, a particle beam processing technique, and a build-up processing technique. The microstructure is selected from the group consisting of a hole-shaped structure, a line structure, and an optical structure. The manufacturing method of the disclosure effectively improves processing efficiency and precision, and through the integration of diverse processing techniques combined with innovative substrate pre-processing and sidewall repair solutions, it enhances process flexibility, production efficiency, and structural reliability.

### CROSS-REFERENCE TO RELATED APPLICATION

This application claims priority to U.S. Provisional Patent Application No. 63/712,155, filed on Oct. 25, 2024; claims priority to U.S. Provisional Patent Application No. 63/810,435, filed on May 22, 2025; claims priority to U.S. Provisional Patent Application No. 63/860,750, filed on Aug. 9, 2025; claims priority to U.S. Provisional Patent Application No. 63/878,302, filed on Sep. 9, 2025; and claims priority from Taiwan Patent Application No. 114140823, filed on Oct. 22, 2025, each of which is hereby incorporated herein by reference in its entireties.

### BACKGROUND OF THE DISCLOSURE

### 1. Field of Disclosure

The disclosure relates to a technology concerning a semiconductor device, and more particularly to a semiconductor device and methods for manufacturing and inspecting the same.

### 2. Related Art

As semiconductor technology trends toward heterogeneous integration and miniaturization, manufacturing high aspect ratio and high-precision microstructures, such as through-substrate vias (TSVs) or precise micro-optical structures, on hard and brittle substrates like silicon, glass, and silicon carbide has become a critical technology. The semiconductor industry has long followed a pattern of slicing first, then processing microstructures on thinned wafers with poor mechanical strength, which often leads to yield issues such as warping and breakage, thereby increasing process complexity.

Conventional processes such as photolithography-etching or mechanical drilling often face problems such as slow processing speed, severe tool wear, poor sidewall roughness, or susceptibility to chipping when dealing with high-hardness materials or high aspect ratio structures. Even with more advanced single processes, such as laser processing, challenges like heat-affected zones or uneven material modification often occur. Furthermore, methods such as wet chemical etching are limited by material and etching direction selectivity, making it difficult to meet diverse structural requirements.

In addition, in the case of metal filling after through-hole formation, effectively inspecting the quality of the filling to ensure structural electrical performance and reliability is a major challenge. Similarly, in the manufacturing of optical components, accurately controlling the profile and surface quality of gratings or curved surfaces and performing comprehensive optical characteristic inspection directly affects the performance of the final product. Current inspection methods are mostly off-line sampling, which cannot provide immediate process feedback, and it is difficult to effectively detect microscopic structural defects such as micro-cracks in the inner walls of microstructures (e.g., through-holes) or voids in the metal filling. Consequently, the detection of defects could lead to the scrapping of the entire batch of products, resulting in high costs.

Therefore, there is an urgent industry need for a more flexible, high-efficiency, and quality-assured integrated solution for microstructure manufacturing and inspection to overcome the bottlenecks of the aforementioned conventional technologies.

### SUMMARY OF THE DISCLOSURE

In view of the problems of the aforementioned conventional technologies, an objective of the disclosure is to provide a method for manufacturing a semiconductor device, a method for inspecting a semiconductor device, and a semiconductor device fabricated by the manufacturing method, in order to resolve the challenges of efficiency, precision, and quality control in conventional processes.

To achieve the foregoing objective, the disclosure proposes a method for manufacturing a semiconductor device, the method comprising the steps of: providing at least one substrate; and utilizing at least one processing technique selected from a group consisting of a laser processing technique, a microwave processing technique, a radio frequency (RF) processing technique, an electrical discharge machining (EDM) technique, a wet chemical processing technique, a mechanical processing technique, a plasma source processing technique, a particle beam processing technique, and a build-up processing technique, to form at least one microstructure on the substrate, wherein the microstructure may be a hole-shaped structure, a line structure, or an optical structure.

To achieve the foregoing objective, the disclosure further proposes a method for inspecting a semiconductor device, used for quality inspection of a structure formed by the aforementioned method, which may utilize a technology based on the interaction of electrical and magnetic properties, or a measurement and analysis technology based on optical principles.

To achieve the foregoing objective, the disclosure further proposes a semiconductor device, which has a structure formed by the aforementioned manufacturing method.

Based on the above, the disclosure provides a complete technical solution encompassing substrate preparation, microstructure formation, sidewall repair, precision polishing, on-line inspection (also referred to as in-line inspection), and final device integration. It not only integrates various advanced processes to meet different application requirements but also effectively improves the efficiency, precision, and reliability of semiconductor device manufacturing through innovative process flows and inspection feedback mechanisms, thereby possessing high industrial utilization value.

The semiconductor device and methods for manufacturing and inspecting the same of the disclosure have the following advantages:
(1) Integration of diverse processing techniques: The disclosure integrates multiple processing methods such as laser, electrical discharge, plasma, and chemical processing. This overcomes the limitations of traditional single processes when handling hard and brittle materials or high aspect ratio structures, and allows for flexible selection or combination of the optimal processing sequence to enhance process flexibility and efficiency.
(2) Proposal of an innovative “Ingot Pre-processing Method”: The fabrication of key microstructures such as high aspect ratio through-holes is completed when the substrate is still in the block-shaped ingot stage, where its mechanical strength is optimal, and then the slicing process is performed. This fundamentally avoids yield loss caused by warping or breakage during the processing of thinned wafers, which not only simplifies the process but is also more conducive to large-scale production.
(3) Proposal of a sidewall repair solution: To address problems such as sidewall roughness or micro-cracks generated during various processing techniques, the disclosure proposes a sidewall repair technology. This could not only reduce surface roughness but also fill potential defects, thereby significantly improving the mechanical strength and electrical reliability of the microstructure.
(4) Integration of in-line inspection (also referred to as on-line inspection) technology: Non-destructive inspection technology is directly integrated into the production line, replacing the traditional time-consuming and inefficient off-line sampling inspection. This allows for real-time quality monitoring and process feedback.

In order to enable the examiner to have a further understanding and recognition of the technical features of the disclosure, preferred embodiments in conjunction with detailed explanation are provided as follows.

### BRIEF DESCRIPTION OF THE DRAWINGS

FIG. 1 is a schematic flowchart illustrating the steps of a method for manufacturing a semiconductor device according to the disclosure.

FIGS. 2A to 2C are schematic cross-sectional views of substrates provided by the method for manufacturing a semiconductor device according to the disclosure, wherein FIG. 2A shows a sliced wafer, FIG. 2B shows a block structure before a sliced process, and FIG. 2C shows a substrate with a predetermined structure formed thereon.

FIG. 3 is a schematic cross-sectional view illustrating the direct formation of a microstructure on a substrate using a direct formation method in the method for manufacturing a semiconductor device according to the disclosure, wherein a stage is omitted for simplification.

FIGS. 4A to 4B are schematic cross-sectional views illustrating the indirect formation of a microstructure on a substrate using an indirect formation method in the method for manufacturing a semiconductor device according to the disclosure.

FIGS. 5A to 5D are schematic cross-sectional views illustrating multiple sidewall repair steps in the method for manufacturing a semiconductor device according to the disclosure.

FIGS. 6A to 6E are schematic process cross-sectional views of a first embodiment of the method for manufacturing a semiconductor device according to the disclosure, which is applied to an ingot pre-processing method.

FIGS. 7A to 7B are schematic process cross-sectional views of a second embodiment of the method for manufacturing a semiconductor device according to the disclosure, which is applied to a process for an advanced packaging silicon carbide interposer.

FIG. 8 is a schematic process cross-sectional view of a third embodiment of the method for manufacturing a semiconductor device according to the disclosure, which is applied to a process for an optical component.

FIG. 9 is a schematic cross-sectional view of a method for inspecting a semiconductor device according to a fourth embodiment of the disclosure, which is applied to on-line eddy current inspection for metal filling quality.

FIG. 10 is a schematic view illustrating the inspection of a substrate by an XRT inspection technique in the method for inspecting a semiconductor device according to the disclosure.

### DETAILED DESCRIPTION OF THE DISCLOSURE

In order to understand the technical features, content and advantages of the disclosure and its achievable efficacies, the disclosure is described below in detail in conjunction with the figures, and in the form of embodiments, the figures used herein are only for a purpose of schematically supplementing the specification, and may not be true proportions and precise configurations after implementation of the disclosure; and therefore, relationship between the proportions and configurations of the attached figures should not be interpreted to limit the scope of the claims of the disclosure in actual implementation. In addition, in order to facilitate understanding, the same elements in the following embodiments are indicated by the same reference numbers. And the size and proportions of the components shown in the drawings are for the purpose of explaining the components and their structures only and are not intending to be limiting.

Unless otherwise noted, all terms used in the whole descriptions and claims shall have their common meaning in the related field in the descriptions disclosed herein and in other special descriptions. Some terms used to describe in the present disclosure will be defined below or in other parts of the descriptions as an extra guidance for those skilled in the art to understand the descriptions of the present disclosure.

The terms such as “first”, “second”, “third” and “fourth” used in the descriptions are not indicating an order or sequence, and are not intending to limit the scope of the present disclosure. They are used only for differentiation of components or operations described by the same terms.

Moreover, the terms “comprising”, “including”, “having”, and “with” used in the descriptions are all open terms and have the meaning of “comprising but not limited to”.

It should be understood that specific details of elements or steps that are not described in detail in this specification may be implemented using conventional techniques in the art. A person of ordinary skill in the art to which the disclosure pertains should understand that the specific equipment, operating parameters, or non-core auxiliary steps of the various processing techniques (e.g., laser processing technique, electrical discharge machining technique, plasma source processing technique, etc.) mentioned in the disclosure, if not specifically limited, could be realized by referring to common knowledge or conventional techniques in the art, and various changes or modifications thereof do not depart from the scope intended to be protected by the disclosure.

### General Embodiment (Manufacturing of a Semiconductor Device)

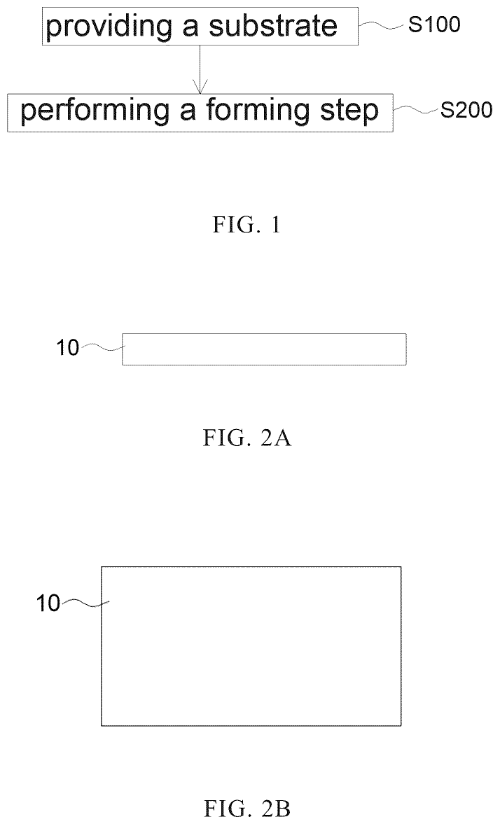

The disclosure provides a semiconductor device, a method for manufacturing a semiconductor device, and a method for inspecting a semiconductor device. The method for manufacturing a semiconductor device of the disclosure is not limited to a specific substrate material or microstructure pattern, but covers a flexible combination of multiple processing techniques under a common inventive concept. This general embodiment is intended to illustrate the core steps of the disclosure and is applicable to any subsequent specific embodiment. As shown in FIG. 1, the method for manufacturing a semiconductor device of the disclosure comprises the steps of: providing a substrate (Step S100); and performing a forming step (Step S200) for forming at least one microstructure on the substrate.

### Regarding Step S100: Providing a Substrate.

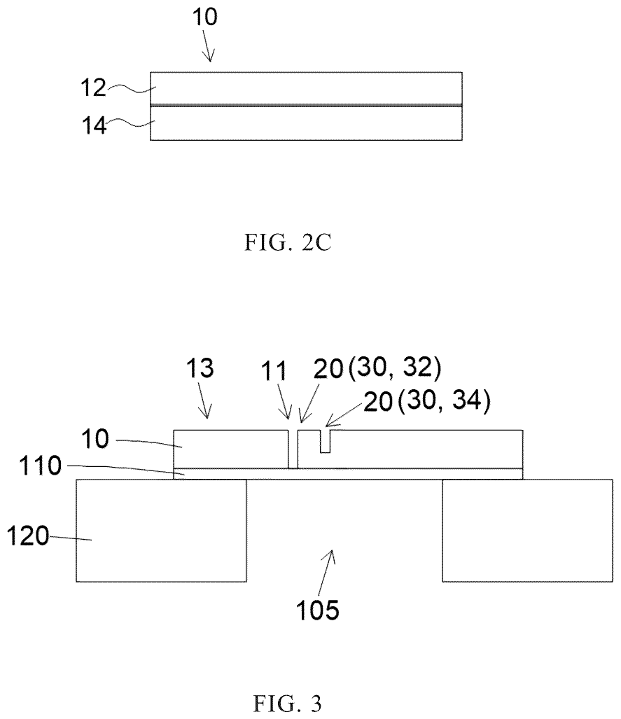

As shown in FIGS. 1 and 2A to 2C, the method for manufacturing a semiconductor device of the disclosure starts with providing at least one workpiece, referred to as a substrate 10, the quantity of which may be one or a plurality. The manner of providing the substrate 10, its material, and its external shape may include but are not limited to the following aspects: The substrate 10 may be in the form of a sliced wafer or plate (as shown in FIG. 2A), with a thickness ranging, for example, from 50 μm to 1,500 μm. In one case, the substrate 10 may also be, for example, a lens, the microstructure 20 being formed on the lens, and the lens having a function selected from a group consisting of turning light, reflecting light, refracting light, and diffracting light. The lens is, for example, a lens made of a material containing silicon atoms or oxygen atoms, or for example, a lens made of a semiconductor material, or a lens made of an N-type semiconductor, a semi-insulating semiconductor, or a material with a refractive index greater than 1.5 (e.g., silicon carbide (SiC) with a refractive index greater than 2). In a preferred and innovative aspect, the substrate 10 may also be a block structure that has not yet undergone a sliced process (as shown in FIG. 2B), such as an ingot, a crystal rod, a puck, or a boule, the thickness of which may be, for example, greater than 5 mm, so as to utilize its excellent mechanical strength to avoid the risk of easy breakage of a thinned substrate 10 in the subsequent step of forming the microstructure. The material of the substrate 10 may include, but is not limited to, a material selected from a group consisting of silicon dioxide, silicon, gallium arsenide, indium phosphide, silicon carbide, gallium nitride, gallium oxide, glass, lithium tantalate, lithium niobate, polyimide, diamond, and metal, but is not limited to the examples described above. The external shape of the substrate is, for example but not limited to, selected from a group consisting of a cylinder, a cuboid, a multifaceted shape, and an irregular shape.

In addition, the disclosure could also provide the substrate 10 through, for example, a bonded structure separation technique. The substrate 10 could be provided by the following steps, for example: providing a bonded structure, the bonded structure comprising a first wafer and a second wafer bonded to each other; and separating the bonded structure using a cutting technique to obtain the substrate 10. The cutting technique is selected from a group consisting of laser processing, slurry wire sawing, diamond wire sawing, and wire electrical discharge machining (WEDM). Furthermore, after separating the bonded structure using the cutting technique, the disclosure further comprises performing at least one process selected from a group consisting of a grinding process, a lapping process, and a polishing process on the obtained substrate. The first wafer is, for example, a polycrystalline silicon carbide wafer, and the second wafer is, for example, a silicon carbide wafer on which a partial process has been completed. The first wafer and the second wafer comprise materials selected from a group consisting of silicon, silicon dioxide, silicon carbide, lithium tantalate, lithium niobate, indium phosphide, gallium nitride, gallium oxide, polyimide, diamond, and metal. Specifically, for example, the disclosure could perform conductive bonding on a P-type polycrystalline silicon carbide wafer 12 and an N-type single-crystal silicon carbide wafer 14, and then separate them using a cutting technique (such as WEDM, slurry wire sawing, or diamond wire sawing, etc.) to obtain the substrate 10 formed with a predetermined structure (as shown in FIG. 2C), the substrate 10 being, for example but not limited to, a “SiC on Poly-SiC wafer” and a “thinned silicon carbide wafer.”

### Regarding Step S200 (Performing a Forming Step).

Please refer to FIGS. 1, 2A, 3, and 4A to 4B. Taking the substrate 10 shown in FIG. 2A as an example, the method for manufacturing a semiconductor device of the disclosure performs at least one forming step (S200) on the substrate 10 to form at least one microstructure 20 on the surface or inside a processing target region 11 of the substrate 10. The disclosure may optionally fix the substrate 10 on a stage 120, for example, by using an adhesive layer 110 (such as a conductive or non-conductive adhesive) or a fixture (such as a clamp). The stage 120 may have a hollow region 105, which corresponds to the position on the ingot where the microstructure 20 is scheduled to be formed, to facilitate the penetration of energy used in the subsequent processing technique or the removal of debris generated by the processing technique.

The microstructure 20 mentioned above is, for example but not limited to, at least one or a combination (i.e., at least two or more) selected from a group consisting of a hole-shaped structure 30, a line structure, and an optical structure. The hole-shaped structure 30 is, for example, a through via 32 that penetrates the substrate 10 (e.g., Through Silicon Via (TSV), Through Glass Via (TGV), or Through Silicon-Carbide Via (TSV-SiC, also referred to as TSiCV)) or a blind via 34 that does not penetrate the substrate 10, and the hole-shaped structure 30 is used, for example but not limited to, as an interconnecting hole. In addition, the hole-shaped structure 30 is, for example but not limited to, characterized by at least one of the following features: a diameter ranging from about 0.01 μm to about 300 μm; an aspect ratio ranging from about 100:1 to about 1:10; an average sidewall surface roughness of less than about 5 μm; and a taper angle greater than about 70 degrees. The line structure is, for example but not limited to, a Redistribution Layer (RDL), an interconnect structure, or a local interconnect structure. The optical structure includes, but is not limited to, a structure selected from a group consisting of a grating structure (e.g., a surface relief grating or a volume holographic grating), a waveguide structure (e.g., a geometric light waveguide structure or a diffractive light waveguide structure), and a curved surface structure. The grating structure or the curved surface structure is a one-dimensional, two-dimensional, or three-dimensional structure. The grating structure may be a vertical grating or a slanted grating. The material of the waveguide structure is the same as or different from the material of the substrate 10.

Regarding the processing technique performed in the forming step (S200) of the method for manufacturing a semiconductor device of the disclosure, it could be broadly divided into “subtractive processing techniques,” “build-up processing techniques,” or a combination thereof.

The “subtractive processing technique” may include, but is not limited to: at least one processing technique selected from a group consisting of a laser processing technique, a microwave processing technique, a radio frequency (RF) processing technique, an electrical discharge machining (EDM) technique, a wet chemical processing technique, a mechanical processing technique, a plasma source processing technique, and a particle beam processing technique. The above-mentioned EDM technique may also be, for example, an EDM technique that uses a discharge electrode to perform a processing technique through physical spark erosion. In one aspect, the disclosure could optionally use a nano-imprinting method to partially cover a surface of the discharge electrode with a non-conductive material pattern to define a discharge region, whereby the EDM technique could correspondingly adjust a width or a depth of the microstructure 20 by adjusting a size of the discharge region defined by the non-conductive material pattern or a thickness of the non-conductive material pattern. The disclosure could also apply discharge energy to the substrate 10 via the discharge electrode, guided by a magnetic field, to guide the discharge behavior of the discharge electrode, which could be used, for example, to adjust a morphology of the microstructure 20. Similarly, the EDM technique of the disclosure could optionally adjust a morphology of the microstructure 20 by adjusting the discharge parameters of the discharge electrode. Furthermore, in one embodiment, the EDM technique could be, for example, an electrochemical discharge machining (ECDM) technique. The ECDM technique performs processing on the substrate 10 via an electrolyte (e.g., potassium hydroxide), so it is not only suitable for conductive substrates but also for non-conductive hard and brittle materials (e.g., optical glass, quartz glass) or semi-insulating materials (e.g., semi-insulating silicon carbide) of the substrate 10. In one aspect, the disclosure could also optionally perform a direct-write lithography processing technique using a laser processing technique or a particle beam processing technique, such as laser direct writing, electron beam direct writing, atom beam direct writing, or ion beam direct writing, to define the pattern of the desired microstructure 20 on the substrate 10 (e.g., a thinned plate or a block structure that has not yet been sliced). The above-mentioned wet chemical processing technique is, for example but not limited to, using chemicals selected from a group consisting of perfluoroalkanes, hydrofluoric acid, hydrochloric acid, sulfuric acid, nitric acid, phosphoric acid, ammonia, ammonium fluoride, potassium hydroxide, ozone, and ozonated water. This wet chemical processing technique could further optionally be combined with at least one auxiliary technique: applying ultrasonic vibration; providing bubbles in a liquid (e.g., an etching solution or other chemical solution) and causing the bubbles to burst to generate burst energy; causing the liquid (e.g., an etching solution or other chemical solution) to absorb energy (e.g., laser energy) to generate an explosive pressure wave; or causing the liquid (e.g., an etching solution or other chemical solution) to absorb energy (e.g., laser energy) to generate a plasma shock wave. The plasma source of the plasma source processing technique is selected from one of a group consisting of a remote plasma source (RPS), an inductively coupled plasma (ICP), a capacitively coupled plasma (CCP), and a surface wave coupled plasma (SWCP). In one aspect, the microwave processing technique, in addition to being used as a heat source, could also, for example, use focused high-energy microwaves to locally or globally heat the substrate 10, causing it to vaporize or melt and splatter to directly remove the material of the substrate 10. The RF processing technique, in addition to also being used as a heat source, could also, for example, use RF energy to directly locally or globally heat and ablate the substrate 10, or to excite a process gas to generate plasma for etching.

The “build-up processing technique” may include, but is not limited to, a process selected from a group consisting of an adhesion process, a coating process, a film formation process, a plating process, an electroplating process, an atomic layer deposition (ALD) process, and an additive manufacturing process.

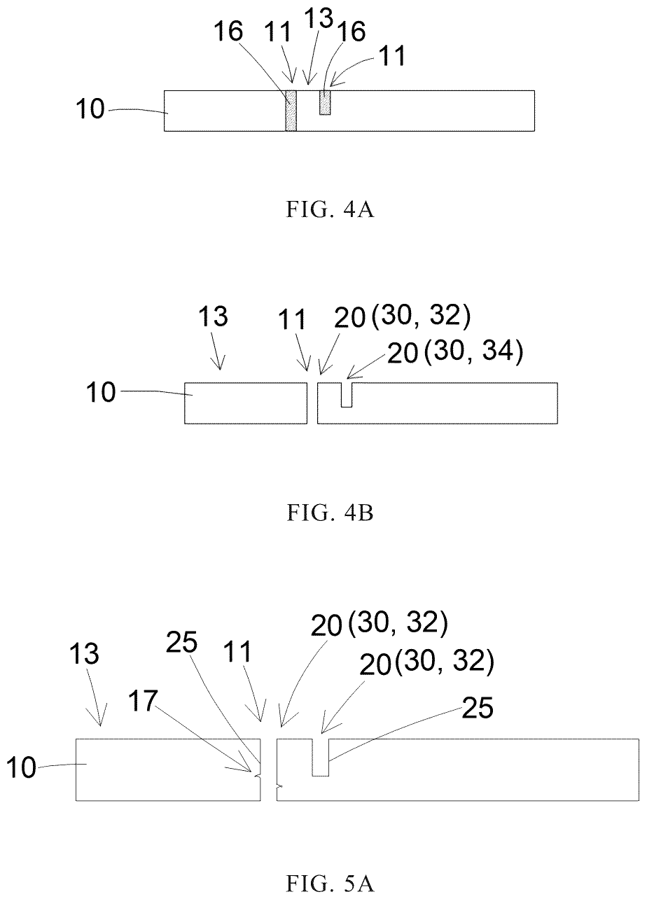

Furthermore, the processing technique performed in the forming step (S200) of the disclosure could be realized through any of the following paths or a combination thereof:
1. Direct (Single-Stage) Formation Method for Directly Forming the Microstructure 20: As shown in FIG. 3, the material of the substrate 10 is directly removed through a single or multiple processing techniques to form the required microstructure 20 on the surface or inside the substrate 10. Specifically, the disclosure, for example but not limited to, directly uses a mechanical processing technique (e.g., mechanical drilling, micro-milling, or imprinting process), an EDM technique, or other processing techniques to form the microstructure 20 (e.g., the hole-shaped structure).
2. Indirect (Two-Stage or More) Formation Method for Indirectly Forming the Microstructure: As shown in FIGS. 4A to 4B, first, a modification step is performed, utilizing a first energy source (e.g., a laser source or a particle beam energy source) to irradiate the processing target region 11 of the substrate 10, thereby providing a first energy to form a modified layer 16 inside or on the surface of the processing target region 11 of the substrate 10, the physical or chemical properties of which have been changed. Subsequently, a removal step is performed, utilizing a second energy source (e.g., a laser source or a plasma source) to provide a second energy, or using chemicals (e.g., wet chemical etchants, electrical discharge machining, or plasma), a particle beam processing technique, or a mechanical processing technique to selectively and efficiently remove the weakened modified layer 16, thereby forming the required microstructure 20. In this modification step and/or removal step, the disclosure could further optionally combine the use of multiple energy sources (e.g., microwave energy or RF energy that could generate a forward cycle effect with laser energy) to produce a synergistic effect, thereby significantly improving processing efficiency.

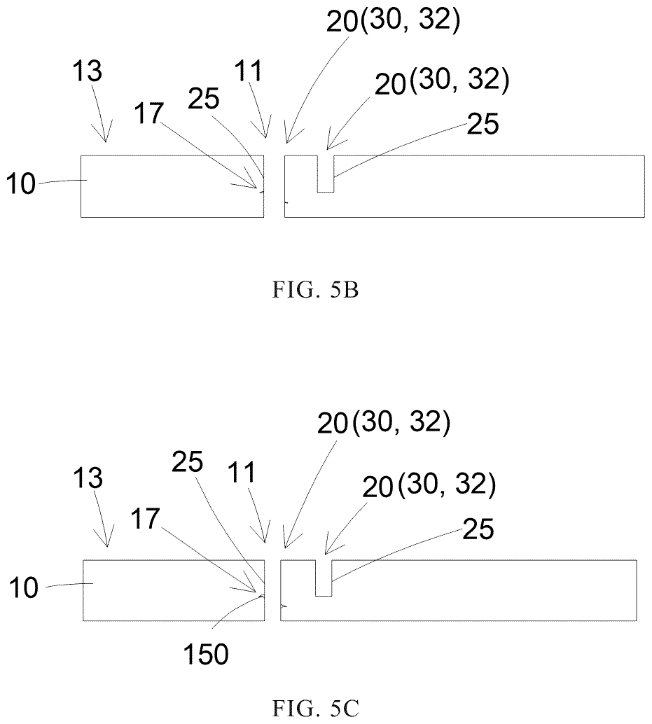

Furthermore, after the microstructure 20 is formed or during its formation, the disclosure could also perform subsequent steps as needed, such as performing a sidewall repair step on the sidewall 25 of the microstructure 20 (as shown in FIGS. 5A to 5D), thereby achieving a repair or optimization effect such as reducing the roughness of the sidewall 25 of the microstructure 20 or avoiding the phenomenon of chipping. For example, the method could then fill the microstructure 20 (e.g., the hole-shaped structure 30 such as the through via 32) with a metal material or form an anti-crack bonding layer (e.g., an insulating coating) to prevent the expansion of defects on the sidewall 25. The material of the anti-crack bonding layer could be an insulating material, a semi-insulating material, or a conductive material.

Alternatively, the resulting semiconductor device (e.g., the microstructure 20 or the substrate 10 filled with the metal material) could be subjected to in-line (also referred to as on-line) quality inspection. Alternatively, the substrate 10 with the microstructure 20 could be bonded with other functional units (e.g., at least one selected from a group consisting of a computing unit, a memory unit, an input/output unit, and a carrier board) to be integrated into a high-level semiconductor device.

Alternatively, after, during, or before the formation of the microstructure 20, and before, after, or during the subsequent steps mentioned above, the disclosure could also perform a planarization treatment process on the surface of the resulting semiconductor device (e.g., the microstructure 20 or the substrate 10) as needed, to reduce profile variations (e.g., total thickness variation, warp, or bow) and/or to reduce surface roughness. This planarization treatment process is, for example but not limited to, using one or more processes selected from a group consisting of a dry etching processing technique, a wet etching processing technique, a chemical mechanical polishing (CMP) processing technique, the laser processing technique, the plasma source processing technique, the EDM technique, and the particle beam processing technique. The planarization treatment process could further optionally be combined with at least one element selected from a group consisting of a heat source, a cold source, and an ultrasonic wave to improve processing efficiency.

Alternatively, after the microstructure 20 is formed or during its formation, the disclosure could further optionally perform a grinding or polishing process as needed, to perform a conformal processing on a processing target surface of the microstructure 20 or the substrate 10, thereby obtaining a predetermined processing morphology. The grinding or polishing process could optionally include providing an energy, which may be, for example but not limited to, laser energy or particle beam energy. In addition, after the disclosure forms the microstructure 20 (e.g., Through Silicon-Carbide Via (TSV-SiC or TSiCV)) on the substrate 10, it could optionally perform a cleaning step (e.g., cleaning with ozonated water (DIO3), particle beam (e.g., atomic beam) treatment) and/or the aforementioned sidewall repair step (e.g., forming an anti-crack bonding layer) based on the requirements (e.g., the degree of repair needed). The material of the anti-crack bonding layer could be an insulating material, a semi-insulating material, or a conductive material. Furthermore, the disclosure could also, for example, first perform the inspection procedure described later on the substrate 10 formed with the microstructure 20 to obtain its degree of repair needed, and then determine the extent of implementation of the aforementioned sidewall repair step (e.g., ozonated water (DIO3) cleaning, particle beam (e.g., atomic beam) treatment, or forming an anti-crack bonding layer), for example, determining the thickness or size of the anti-crack bonding layer based on the degree of repair needed.

Through the method disclosed in the above general embodiment, the disclosure provides a highly flexible and innovative manufacturing framework, the specific implementations of which will be detailed in the subsequent embodiments.

To more clearly define the disclosure, some of the technical features and terminology mentioned in the foregoing embodiments are supplemented as follows:

As shown in FIG. 3 and FIGS. 4A to 4B, in the processing process (e.g., modification and/or removal step) of forming the microstructure by the direct formation method or by the indirect formation method, the disclosure could optionally combine the use of microwave energy or RF energy to interact (or a synergistic effect) with the first energy (e.g., laser energy or particle beam energy) used in the direct or indirect formation method, thereby generating a forward cycle effect and creating a larger thermal difference and physical property difference between the processing target region 11 and the non-processing target region 13, such as differences in stress, structural strength, lattice type, or hardness, which facilitates the modification and/or removal of the substrate material. Specifically, when the first energy (e.g., laser energy or particle beam energy) irradiates (acts upon) the processing target region 11 of the substrate 10, the material in the processing target region 11 is ionized due to a nonlinear absorption effect, which in turn generates free electrons. The presence of these free electrons enables the processing target region 11 of the substrate 10 to absorb the second energy (e.g., microwave energy or RF energy) more effectively compared to the non-processing target region 13 that is not irradiated (acted upon), thereby rapidly increasing the temperature of the processing target region 11. The increase in temperature, in turn, helps the processing target region 11 of the substrate 10 absorb more energy from the first energy source (laser source or particle beam energy source), thereby generating more free electrons.

Thus, a complete self-reinforcing cycle (also referred to as forward cycle) is formed: the free electrons generated by the laser energy absorb the microwave energy or RF energy, leading to a rapid temperature increase; subsequently, this high-temperature state, in turn, promotes the generation of more free electrons, causing the entire process to continuously accelerate and enhance. This forward cycle effect significantly shortens the time required for the overall processing technique and allows the same processing goal to be achieved with lower total energy input, thereby significantly improving processing efficiency and precision.

Furthermore, please continue to refer to FIGS. 5A to 5D, and also refer to FIGS. 1 to 4B. As mentioned before, after the formation of the microstructure 20 shown in FIG. 3 or FIG. 4B, the disclosure could optionally perform a sidewall repair step as needed.

The purpose of the sidewall repair step of the disclosure is to repair or optimize (refine) the sidewall 25 of the microstructure 20 to reduce the surface roughness of the sidewall 25 of the microstructure 20 and/or to fill defects 17 such as cracks that may be generated during the formation of the microstructure 20 in the forming step (S200) (as shown in FIG. 5A), thereby preventing the defect 17 from continuously expanding and strengthening the overall structure.

This sidewall repair step may include one or more of the following methods:

Energy Processing: Using an energy to perform non-contact grinding or polishing on the sidewall 25 of the microstructure 20, such as a laser processing technique, an EDM technique, a plasma source processing technique, or a particle beam processing technique (as shown in FIG. 5B). For example, the disclosure could clean the sidewall 25 of the microstructure 20 (e.g., the line structure such as RDL) with ozonated water (DIO3) and/or provide a plasma source (e.g., remote plasma source, RPS) to repair and optimize the sidewall 25 of the microstructure 20 (e.g., a hole-shaped structure such as a silicon carbide through via) to reduce its surface roughness and minimize the occurrence of chipping.

Physical Polishing: Performing a grinding or polishing process mechanically, for example, using grinding powder, slurry, or contact-type flexible wire (e.g., cotton thread) or flexible sheet (as shown in FIG. 5B).

Chemical Treatment: Improving the surface of the sidewall 25 through a wet chemical processing technique (e.g., using ozonated water) or atomic layer etching (ALE) (as shown in FIG. 5B).

Defect Filling: Providing a repair material 150 to fill the defect 17 on the sidewall 25 of the microstructure 20. The repair material 150 is, for example but not limited to, silicon oxide (as shown in FIG. 5C). To improve filling efficiency, the disclosure could optionally be combined with heat energy, utilizing a heat source (such as a microwave/RF generation source) to promote a reaction on the surface of the sidewall 25 of the microstructure 20 to generate the repair material, and/or combined with external force perturbation, utilizing an external force perturbation source (such as an ultrasonic wave generation source) to drive the material into the defect 17 of the sidewall 25 of the microstructure 20 to assist in repairing and optimizing the sidewall 25 of the microstructure 20.

Coating Protection: The disclosure could also provide at least one anti-crack bonding layer 160 to cover part or all of the sidewall 25 of the microstructure 20, and at least cover the defect 17 on the sidewall 25 of the microstructure 20, thereby serving as a bonding layer to prevent defects 17 such as cracks on the sidewall 25 from continuously expanding. The anti-crack bonding layer 160 has, for example, ductility and/or insulation, and the material is, for example but not limited to, a polymer such as Parylene. In addition, the anti-crack bonding layer 160 could also be optionally formed on the sidewall 25 of the microstructure 20 by chemical vapor deposition or other coating or deposition methods, as shown in FIG. 5D.

Taking the direct or indirect formation of a microstructure (e.g., Through Silicon-Carbide Via (TSV-SiC or TSiCV)) using a mechanical drilling processing technique as an example, the disclosure could also optionally select a cutting fluid that could react with the material in the through hole of the substrate 10, which could not only form a protective layer that protects the sidewall 25 of the through hole, or provide the effect of protecting the sidewall 25 of the through hole simultaneously during the drilling process, but also achieve the technical effects of reducing roughness, reducing defects 17 such as cracks, and even providing cleaning and inspection functionality incidentally.

As mentioned before, after, during, or before the formation of the microstructure 20, the disclosure could perform an inspection procedure as needed. This inspection procedure includes, for example but is not limited to, an optical inspection step. The inspection procedure of the disclosure could be contact-type, non-contact-type, destructive, or non-destructive inspection. The inspection procedure could be used to perform at least one inspection on the substrate or the microstructure on the substrate selected from a group consisting of material characteristic inspection (e.g., doping concentration, crystal defects, lattice structure, or crystal orientation), external feature inspection (e.g., size, curvature, surface roughness, scratches, or tilt angle of the substrate or the microstructure on the substrate), and optical characteristic inspection. The optical characteristic inspection uses a light source to perform measurement and analysis of an optical characteristic at the same or different wavelengths, the optical characteristic being at least one selected from a group consisting of refractive index, transmittance, reflectance, extinction coefficient, spectral efficiency, diffraction intensity, diffraction efficiency, dispersion, light diffusion angle, light leakage rate, final field of view, information at different light exit angles, light intensity uniformity at different light exit angles, and aberration. The light source is a point light source, a line light source, an area light source, a polarized light source, a laser source, an image source, a single wavelength source, a multi-wavelength source, a standard test source, a standard test image source, or any combination thereof. The optical characteristic could be selected from at least one of a group consisting of refractive index, transmittance, reflectance, extinction coefficient, spectral efficiency, diffraction intensity, diffraction efficiency, dispersion, light diffusion angle, light leakage rate, final field of view, information at different light exit angles, light intensity uniformity at different light exit angles, and aberration. The inspection procedure is performed using at least one instrument selected from a group consisting of an atomic force microscope, a white light interferometer, an ellipsometer, a near-field optical microscope, a scanning acoustic microscope, an X-ray scanning technique, and an electron microscope.

In addition, the disclosure could also optionally integrate the inspection procedure with a manufacturing system for on-line inspection. The inspection procedure, such as the optical inspection procedure, comprises: providing an energy source to interact with the substrate or the microstructure, and performing the inspection based on a change in a feedback signal or a difference in an input and output performance, wherein the energy source is selected from a group consisting of a light source, a force source, and a vibration source. When the optical inspection procedure uses the X-ray scanning technique, the optical inspection step is performed by analyzing a change in an absorption information or a diffraction information of the substrate 10 or the microstructure 20. The method for inspecting a semiconductor device of the disclosure could further optionally include performing a transmission step, used for instantly transmitting the inspection result to a conveying equipment or a process equipment of the manufacturing system, so that the conveying equipment or the process equipment performs a corresponding action based on the received inspection result. The inspection procedure is performed using an inspection device integrated into the conveying equipment or the process equipment. The conveying equipment is an Equipment Front End Module (EFEM). The process equipment is a vapor deposition equipment, a sputtering equipment, a chemical vapor deposition equipment, a physical vapor deposition equipment, an atomic layer deposition equipment, a washing equipment, or a cleaning equipment.

Although the disclosure uses the optical inspection procedure as an illustrative example of the inspection procedure, it is not limited thereto, and the inspection method of the disclosure could also be applied to other types of inspection procedures. Specifically, the method for inspecting a semiconductor device disclosed in the disclosure comprises the steps of: providing a substrate, the substrate being formed with a microstructure, wherein the microstructure is at least one or a combination (i.e., at least two or more) selected from a group consisting of a hole-shaped structure, a line structure, and an optical structure, and the sidewall of the microstructure is lined with or filled inside with a metal material; and performing an inspection procedure, which could utilize a detection technique based on electrical and magnetic properties and their interaction (e.g., eddy current detection technique), and inspect a metal material 50 on the substrate 10 based on a change in a feedback signal or a difference in an input and output performance, thereby obtaining an inspection result having characteristic data of the metal material 50. The characteristic data comprises at least one of the electrical properties, magnetic properties, resistance characteristics, structural density, or structural defects of the metal material 50.

Furthermore, in a feasible embodiment, the inspection procedure of the method for inspecting a semiconductor device of the disclosure could also be applied before the forming step is performed. That is, the disclosure could optionally perform quality inspection on the substrate before the substrate undergoes the above-mentioned forming step, such as but not limited to defect inspection. For example, this inspection method could be, for example, using an X-ray source 80 with an X-ray diffraction topography (XRT) detection technique to inspect the substrate 10 that has not yet been formed with a microstructure. This XRT detection technique uses diffraction information to reveal and analyze crystal defects (such as type, distribution, density, or strain field), and the manner of interaction with the crystal of the substrate could include transmission and/or reflection. The disclosure could optionally inspect a single substrate or inspect a plurality of substrates during the inspection process. For example, as shown in FIG. 10, a plurality of substrates 10 could be stacked together during the inspection process, allowing the inspection X-ray 82 generated by the X-ray source 80 to interact with the plurality of substrates 10 through transmission, thereby forming different diffraction information that could be received by a sensing element 85. Subsequently, by analyzing this diffraction information, the defect information of each substrate 10 is obtained.

### First Embodiment (Ingot Pre-Processing Method)

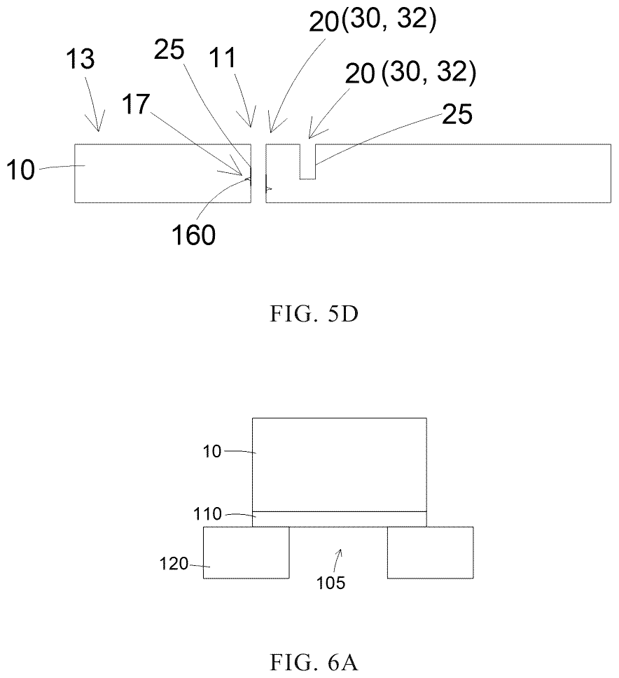

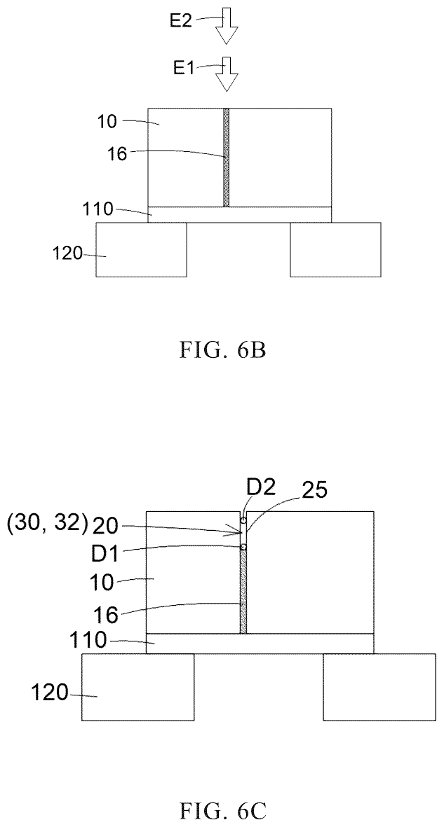

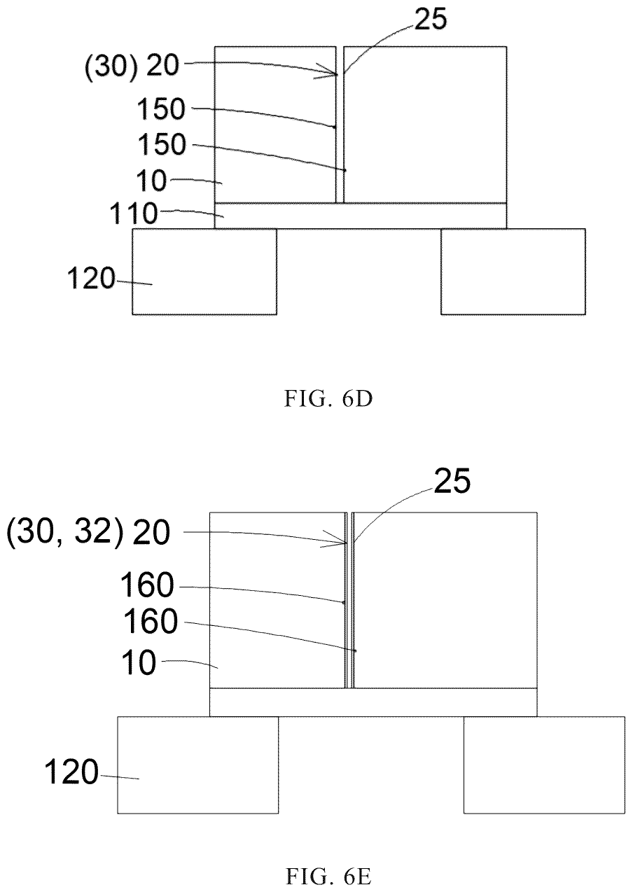

Please continue to refer to FIGS. 6A to 6E and FIGS. 1 to 5, wherein FIGS. 6A to 6E illustrate an innovative ingot pre-processing method disclosed in the first embodiment of the disclosure.

First, a substrate 10 is provided (Step S100). In the first embodiment, the substrate 10 is a block structure, and a silicon carbide (SiC) ingot is taken as an example here. Next, the substrate 10 is fixed onto a stage 120 using a conductive or non-conductive adhesive layer 110 (as shown in FIG. 6A). Alternatively, the disclosure could also use a corresponding fixture to fix the ingot onto the stage 120. In one embodiment, the stage 120 may have a hollow region 105, the hollow region 105 corresponding to the position on the substrate 10 where the microstructure 20 (e.g., the hole-shaped structure 30 such as the through via 32 (as shown in FIG. 6E)) is scheduled to be formed, to facilitate the penetration of energy used in the subsequent processing technique or the removal of debris generated by the processing technique.

The disclosure then performs the forming step S200 on the substrate 10 to form a plurality of microstructures 20 (e.g., the hole-shaped structure 30 such as the through via 32). In this first embodiment, the forming step comprises:
(a) Modification Step: As shown in FIG. 6B, a pulsed laser energy E1 is used to scan the ingot along a predetermined path, causing a modified layer 16 to be formed inside the ingot. In a preferred embodiment of the disclosure, the pulsed laser energy E1 is, for example, an Nd:YAG pulsed laser, an Nd:YVO₄ pulsed laser, or a Ti-Sapphire pulsed laser. The laser parameters could be set, for example, as: wavelength ranging from 700 nm to 1,600 nm, pulse width less than 1,000 ns, and pulse energy ranging from 0.1 μJ to 1,000 μJ. The laser energy is focused inside the ingot, which could cause the material in the processing target region to be ionized to generate free electrons, thereby causing modification phenomena such as atomic bond weakening, structural weakening, or crystal lattice type transformation, to form the modified layer 16. Simultaneously, a microwave energy or RF energy E2 could be optionally provided to interact with the pulsed laser energy E1, thereby generating a forward cycle effect to accelerate the formation of a plurality of modified layers 16 inside the ingot and improve processing efficiency. In the modification step performed on the ingot, in addition to scanning with a pulsed laser, in another embodiment, the disclosure could also use a high-energy particle beam (e.g., electron beam, atomic beam, or ion beam) instead of the pulsed laser energy E1 to form the modified layer 16 on the ingot. Similarly, when the high-energy particle beam performs the modification step, the disclosure could also optionally provide a microwave energy or RF energy E2 to interact with the high-energy particle beam (e.g., electron beam, atomic beam, or ion beam), thereby generating a forward cycle effect.
(b) Removal Step: Next, as shown in FIG. 6C, the modified layer 16 is removed using an electrical discharge machining (EDM) technique, thereby forming the microstructure 20 (e.g., the hole-shaped structure 30) in the ingot. In a preferred embodiment, the removal step further comprises, for example: first, applying a first discharge energy via a first discharge electrode D1 to rapidly remove the modified layer 16 to preliminarily form the hole-shaped structure 30; and then, applying a second discharge energy via a second discharge electrode D2 (or adjusting the discharge parameters of the first discharge electrode D1), the second discharge energy being the same as or different from the first discharge energy, to modify or optimize the sidewall of the preliminarily formed hole-shaped structure 30, for example, to reduce its surface roughness. The reason why the removal step could selectively remove the modified layer 16 is that the processing target region 11 where the modified layer 16 is located has produced a significant difference in stress, structural strength, crystal lattice type, or hardness compared to other unmodified regions (non-processing target region 13) of the ingot. This difference causes the modified layer 16 to have a completely different response to subsequently applied energy (e.g., EDM energy) or chemical etchants, thereby enabling it to be easily and rapidly removed.

After the hole-shaped structure 30 is formed, the disclosure could optionally perform a sidewall repair step. This sidewall repair step could comprise any one or a combination of the following steps:
(a) Cleaning the microstructure with ozonated water (DIO3) and/or providing a plasma source (e.g., remote plasma source, RPS) to treat the sidewall 25 of the hole-shaped structure 30 to reduce its surface roughness (as shown in FIG. 6D).
(b) The sidewall repair step could further provide a repair material 150 (as shown in FIG. 6D) to fill potential defects on the sidewall 25 of the hole-shaped structure 30. This filling process could be combined with the application of heat energy and/or ultrasonic vibration to improve the filling effect and prevent the defects from extending in subsequent processing.
(c) The sidewall repair step could further provide an anti-crack bonding layer 160 to cover part or all of the sidewall 25 of the microstructure 20, and at least cover the defects 17 on the sidewall 25 of the microstructure 20, thereby serving as a bonding layer to prevent defects 17 such as cracks on the sidewall 25 from continuously expanding (as shown in FIG. 6E).
(d) If the hole-shaped structure 30 is directly or indirectly formed using a mechanical drilling processing technique, the composition of the cutting fluid used in the mechanical drilling processing technique is preferably capable of reacting with the material in the through hole of the substrate 10, thereby forming a protective layer to protect the sidewall 25 of the hole-shaped structure 30, or the cutting fluid could simultaneously provide the effect of protecting the sidewall 25 of the through hole during the drilling process.

Next, the disclosure could, for example, perform a slicing process on the ingot that has been formed with the microstructure 20. This first embodiment uses a wire electrical discharge machining (WEDM) technique to slice the ingot into several thinned substrates that already carry the microstructure 20. Finally, a separation step is performed, where the sliced, thinned substrate could be immersed in hot water at a temperature higher than 80 degrees Celsius, an acid solution with a pH value less than 7, or an alkaline solution with a pH value greater than 7, and could be combined with 40 KHz ultrasonic vibration to degrade the adhesive properties of the adhesive layer 110. Alternatively, the disclosure could also provide a light source (such as UV light or laser light) for irradiation to degrade the adhesive layer. In addition, before and after the above-mentioned separation step, the disclosure could optionally perform at least one process selected from a group consisting of grinding, lapping, and polishing on the thinned substrate.

### Second Embodiment (Manufacturing and Integration of an Advanced Packaging SiC Interposer)

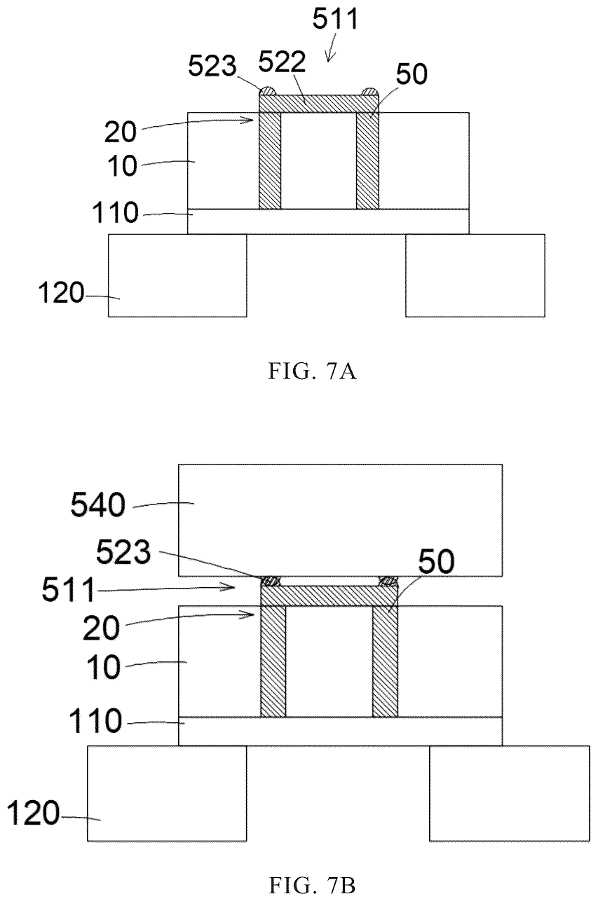

Please refer to FIG. 7. This second embodiment discloses the application of the disclosure in the field of advanced packaging.

As shown in FIGS. 7A and 7B, first, a substrate 10 is provided. The substrate 10 serves as an interposer and could be composed of materials such as an insulating material, a semi-insulating material, or a semiconductor material, for example, silicon, silicon dioxide, glass, or silicon carbide. In this second embodiment, the substrate 10 is exemplified by a silicon carbide substrate. Next, at least one microstructure 20 is formed on the silicon carbide substrate. The microstructure 20 here is exemplified by a Through Silicon-Carbide Via (TSV-SiC or TSiCV). In a preferred embodiment, the formation of the Through Silicon-Carbide Via is, for example but not limited to, adopting a two-stage process: first, a laser processing technique is used to modify the material in the processing target region on the silicon carbide substrate to form a modified layer; and then, a wet chemical processing technique is used to chemically etch and remove the modified layer. To improve etching efficiency, the wet chemical processing technique could be combined with at least one auxiliary technique: applying ultrasonic vibration; providing bubbles in the etching solution and utilizing their burst energy; causing the etching solution to absorb laser energy to generate an explosive pressure wave; or causing the etching solution to absorb laser energy to generate a plasma shock wave.

After the microstructure 20 (e.g., the Through Silicon-Carbide Via) is formed, a conductive structure filling step is performed next. For example, a metal material 50 (e.g., copper, tin, lead, gold, silver, molybdenum (Mo), or ruthenium (Ru)) is filled into the Through Silicon-Carbide Via using metal filling equipment (such as electroplating or sputtering deposition equipment), and a metal layer could be optionally formed on the surface of the silicon carbide substrate to serve as the basis for subsequent metal line formation.

Next, a Redistribution Layer (RDL) 522 is fabricated on the metal layer. In one embodiment, the line pattern of the RDL 522 could be defined, for example, using a standard photolithography process for patterning. Alternatively, a direct-write lithography processing technique could be adopted, for example, a laser direct writing processing technique or a particle beam (e.g., electron beam, atomic beam, or ion beam) direct writing processing technique, to achieve high-precision, maskless patterning and manufacturing. After the line pattern of the RDL 522 is defined, the metal in the non-line area is removed through wet etching or dry etching to form the RDL 522 (or conductive layer) which electrically connects the respective microstructures 20 (e.g., the Through Silicon-Carbide Via). In another embodiment, the RDL 522 could also be formed directly through the aforementioned build-up processing technique or the direct-write lithography processing technique. For example, the additive manufacturing process in the build-up processing technique could be used to directly deposit and pattern the metal material on the substrate 10, or the direct-write lithography processing technique could be used to directly initiate chemical reactions or material phase changes in specific areas of the substrate with a laser beam or particle beam to deposit and pattern the metal material, thereby forming the RDL 522. After the fabrication of the RDL 522 is completed, a contact structure 523, such as a micro bump like a C4 (Controlled Collapse Chip Connection) bump, required for subsequent bonding could be further fabricated on specific end points of the RDL 522. The line pattern of the RDL 522 is located on a surface 511 of the silicon carbide substrate to be bonded, and is formed of a material selected from a group consisting of a conductive material, a semi-insulating material, and an insulating material, and the pattern of the RDL 522 is periodically or non-periodically distributed on the surface 511 to be bonded.

As shown in FIG. 7B, a bonding step is performed. For example, the surface 511 of the silicon carbide substrate that already has the contact structure 523 and is to be bonded is electrically and physically (mechanically) connected to at least one functional unit 540 (e.g., at least one selected from a group consisting of a computing unit, a memory unit, an input/output unit, and a carrier board). This second embodiment uses the functional unit as an example of a carrier board, wherein the carrier board could be selected from a group consisting of an epoxy resin film (i.e., Ajinomoto Build-up Film, ABF) substrate, a bismaleimide-triazine (BT) substrate, a Molded Interconnect Substrate (MIS), and a Printed Circuit Board (PCB). In this second embodiment, the bonding step is performed through at least one method selected from a group consisting of a thermal compression bonding (TCB) technique, a room temperature bonding technique, and a hybrid bonding technique. Furthermore, before performing the bonding step, the disclosure further optionally includes performing a planarization treatment process on the surface 511 of the silicon carbide substrate to be bonded, to reduce profile variations (e.g., total thickness variation, warp, or bow) and/or to reduce roughness. This planarization treatment process uses one or more processes selected from a group consisting of a dry etching processing technique, a wet etching processing technique, a chemical mechanical polishing (CMP) processing technique, the laser processing technique, the plasma source processing technique, the EDM technique, and the particle beam processing technique. The planarization treatment process is further combined with at least one element selected from a group consisting of a heat source, a cold source, and an ultrasonic wave to improve processing efficiency. The plasma source of the plasma source processing technique is selected from one of a group consisting of a remote plasma source (RPS), an inductively coupled plasma (ICP), a capacitively coupled plasma (CCP), and a surface wave coupled plasma (SWCP).

### Third Embodiment (Manufacturing of a High-Precision Optical Component)

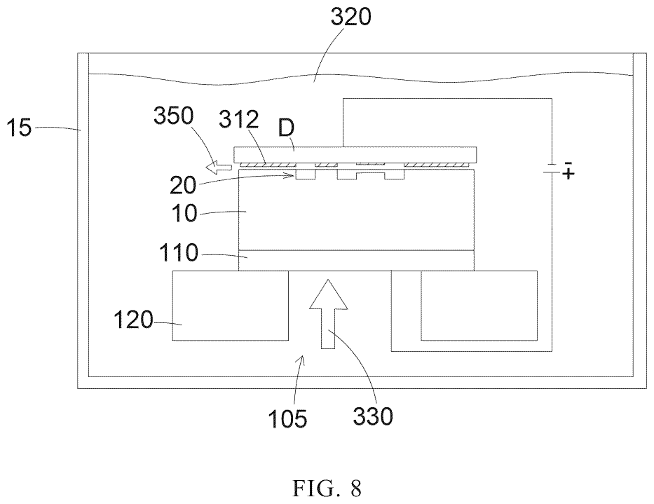

Please refer to FIG. 8 and also refer to other figures. This third embodiment discloses the application of the disclosure in the manufacturing of semiconductor devices such as optical components. This third embodiment uses an optical structure such as a grating structure (e.g., a grating groove) as an illustrative example of the microstructure, but is not limited thereto. The optical structure of the disclosure could also be, for example, a structure selected from a group consisting of a grating structure, a waveguide structure, and a curved surface structure.

First, as shown in FIG. 8, a lens is provided as the substrate 10. The lens is, for example, a lens made of a material containing silicon atoms or oxygen atoms, or for example, a lens made of a semiconductor material, or a lens made of an N-type semiconductor, a semi-insulating semiconductor, or a material with a refractive index greater than 1.5. This third embodiment uses an N-type semiconductor or semi-insulating semiconductor substrate (e.g., silicon carbide (SiC) with a refractive index greater than 2) as an illustrative example of the lens.

Next, the microstructure 20 (e.g., an optical structure such as a grating structure, a waveguide structure, or a curved surface structure) is formed on the substrate 10 (i.e., the lens) according to a predetermined pattern (i.e., a pattern corresponding to the morphology of the microstructure 20).

In a preferred embodiment, the method for manufacturing a semiconductor device of the disclosure could further include, before performing the above-mentioned forming step, first performing a patterning definition step through a nano-imprinting technique to provide a predetermined pattern (i.e., a nano-imprinting pattern corresponding to the morphology of the microstructure 20). This patterning definition step is, for example, forming a non-conductive material on the surface of a conductive material (e.g., a discharge electrode D such as copper metal), thereby forming a non-conductive material pattern 312 corresponding to the morphology of the microstructure 20, wherein the non-conductive material with the non-conductive material pattern 312 partially shields the surface of the discharge electrode D and exposes the other part of the surface of the discharge electrode D, to define a discharge region.

Subsequently, the discharge electrode 310 with the non-conductive material pattern 312 is placed on the substrate 10. The discharge electrode D and the substrate 10 on which the microstructure 20 is to be formed are electrically connected via conductive lines to the positive and negative terminals of a power source, respectively. The substrate 10 is, for example, disposed in a tank 15, which is used to contain a processing fluid 320 (e.g., kerosene, water, or gas). In this third embodiment, the substrate 10 is disposed on the stage 120 via an adhesive layer 110, and the adhesive layer 110 is, for example, a conductive adhesive, thereby enabling the substrate 10 to be electrically connected to the positive terminal of the power source via the adhesive layer 110. Thus, the disclosure could use the EDM technique in a processing fluid 320 environment (e.g., kerosene, water, or gas) to form the microstructure 20 (e.g., an optical structure such as a grating structure, a waveguide structure, or a curved surface structure) on the substrate 10.

When performing the EDM technique in this third embodiment, the following steps could be optionally performed:
(a) An external magnetic field 330 could be applied to guide the discharge behavior of the discharge electrode, which could be used to adjust a morphology of the microstructure 20 (e.g., an optical structure such as a grating structure, a waveguide structure, or a curved surface structure), which helps in forming an optical structure such as a grating structure, a waveguide structure, or a curved surface structure with a vertical or slanted profile.
(b) At least one suction force 350 could be applied via at least one suction source (e.g., a water pump) to guide the processing fluid 320 through channels between the discharge electrode D and the substrate 10, which helps in removing processing debris and improving processing stability.
(c) The discharge parameters of the discharge electrode of the EDM technique could be adjusted to adjust the morphology of the microstructure. For example, the EDM technique could correspondingly adjust a width or a depth of the microstructure 20 (e.g., an optical structure such as a grating structure, a waveguide structure, or a curved surface structure) by adjusting the voltage or current of the EDM technique. Alternatively, the EDM technique of the disclosure could also correspondingly adjust a width or a depth of the microstructure 20 (e.g., an optical structure such as a grating structure, a waveguide structure, or a curved surface structure) by adjusting a size of the discharge region defined by the non-conductive material pattern 312 or a thickness of the non-conductive material pattern 312. The width or depth of the microstructure 20 (e.g., an optical structure such as a grating structure, a waveguide structure, or a curved surface structure) is, for example, less than 10 μm, or even less than 1 μm.

In addition to using the nano-imprinting technique, the disclosure could also optionally perform a direct-write lithography processing technique, such as using laser direct writing, electron beam direct writing, atom beam direct writing, or ion beam direct writing, to define the pattern of the desired microstructure 20 on the substrate 10 (e.g., a thinned plate or a block structure that has not yet been sliced). Furthermore, in another embodiment, the method for manufacturing a semiconductor device of the disclosure could also use a conventional photolithography process to perform patterning definition before forming the microstructure 20, thereby providing a predetermined pattern. For example, a photoresist mask pattern corresponding to the morphology of the microstructure 20 is formed on the surface of the substrate 10. The EDM technique could be the standard Electrical Discharge Machining (EDM) process that uses the discharge electrode D to process the material through physical spark erosion, or the EDM technique of the disclosure could also be combined with or changed to use the Electrochemical Discharge Machining (ECDM) process, which performs discharge machining on the substrate 10 via the processing fluid 320 (e.g., an electrolyte such as potassium hydroxide), thereby being particularly suitable for the substrate 10 of non-conductive hard and brittle materials (e.g., optical glass, quartz glass) or semi-insulating materials (e.g., semi-insulating silicon carbide).

After the microstructure 20 is formed, the disclosure could optionally perform a grinding or polishing process to further repair or optimize its optical surface. The grinding or polishing process performs a conformal processing on a processing target surface with an energy, thereby obtaining a predetermined processing morphology. The grinding or polishing process could be an atomic layer etching (ALE) processing technique, or could use a flexible wire (e.g., cotton thread) combined with a polishing solution, so that the final surface roughness (Ra) could be less than 10 nanometers.

### Fourth Embodiment (Eddy Current On-Line Inspection for Metal Filling Quality)

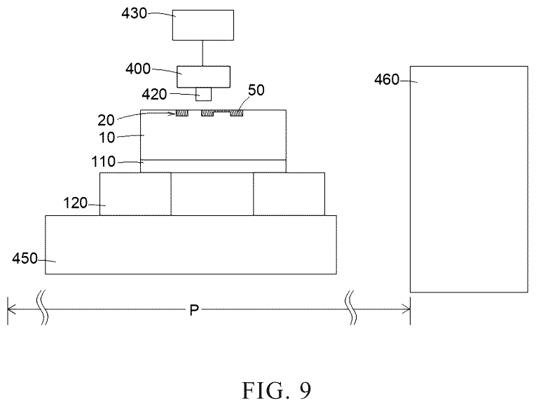

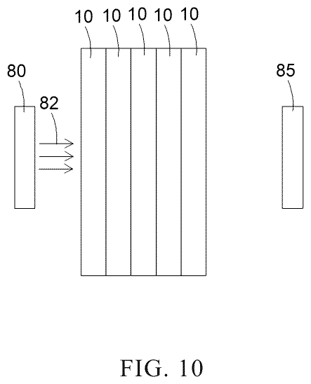

Please refer to FIG. 9. This fourth embodiment discloses a non-destructive inspection solution integrated into a production line, used for real-time monitoring of the quality of metal filling in the microstructure manufactured according to the preceding embodiments, thereby overcoming the problems of delay and high scrap cost caused by off-line sampling inspection in conventional techniques.

In a specific embodiment, as shown in FIG. 9, the inspection system 400 of the disclosure could be optionally integrated into a conveying equipment 450 or a process equipment 460. The process equipment 460 is a semiconductor process equipment, such as a vapor deposition equipment, a sputtering equipment, a chemical vapor deposition equipment, a physical vapor deposition equipment, an atomic layer deposition equipment, a washing equipment, or a cleaning equipment. The conveying equipment 450 is, for example, an Equipment Front End Module (EFEM). In this fourth embodiment, the inspection system 400 is illustrated by being integrated into an EFEM. The core of the inspection system 400 is an Eddy Current probe 420, which is strategically disposed on the wafer conveying path P of the EFEM and could perform on-line inspection without the need for additional conveying time.

In the inspection flow, a substrate 10 manufactured according to the second embodiment or other embodiments, and which has been completed with the metal material 50 filled in the microstructure 20, could be conveyed, for example, by a robot arm of the EFEM and passed through the Eddy Current probe 420 of the inspection system 400. The Eddy Current probe 420 could generate a time-varying magnetic field around it, and the time-varying magnetic field could induce an eddy current in the metal material 50 in the microstructure 20 of the substrate 10. The characteristics of the metal material 50 (such as density, presence of voids or cracks) will affect the distribution of the eddy current, thereby changing the reverse magnetic field generated by itself. Therefore, the Eddy Current probe 420 could detect a change in the probe's own impedance or magnetic field caused by the eddy current, and transmit this signal to a processing unit of a central controller 430. The inspection system 400, the conveying equipment 450, and/or the process equipment 460 are electrically connected to the central controller 430, for example, wirelessly or via a wire.

The central controller 430 could interpret and analyze the received signal by its processing unit, thereby determining the characteristic data of the metal material 50, such as its electrical properties, magnetic properties, resistance characteristics, structural density, or the existence of defects such as voids. A feature of the disclosure is that this inspection solution is not only a screening for defective products but also constitutes a closed-loop intelligent production model, where the quantified inspection result is instantly transmitted to the central controller 430. The central controller 430 could not only instantly issue instructions to cause the EFEM to sort defective products (NG, No Good) into specific cassettes but could also instantly feed back (real-time feedback) process deviation data (e.g., continuously low metal filling density in a certain area) to the metal filling equipment (such as electroplating or sputtering deposition equipment) in the preceding process step, which could dynamically adjust its process parameters accordingly, for example, fine-tuning the electroplating current density or temperature, thereby instantly correcting the process deviation to prevent the occurrence of large-scale defects. Therefore, the disclosure could improve yield and performance.

In summary, the semiconductor device and methods for manufacturing and inspecting the same of the disclosure overcome the bottlenecks of the prior art through a series of innovative integrations, which may have one or more of the following key advantages:
(1) Integration of diverse processing techniques, allowing for the selection or combination of the optimal processing method for different material and structural requirements, thereby greatly enhancing process flexibility and efficiency. The disclosure integrates multiple processing techniques such as laser, electrical discharge, plasma, and chemical processing, which overcomes the processing limitations of conventional single processes on hard and brittle materials and high aspect ratio structures. This solution allows for the flexible selection or combination of optimized processing sequences for different requirements, achieving manufacturing goals that are both efficient and precise.
(2) Proposal of an innovative “Ingot Pre-processing Method,” where the microstructure fabrication is completed before the substrate is sliced, utilizing the mechanical strength of the block structure, simplifying the process, and facilitating batch production. The disclosure proposes completing the fabrication of key microstructures during the block ingot stage before the substrate is sliced. This method fully utilizes the excellent mechanical strength of the ingot, fundamentally avoiding the yield loss caused by warping or breakage during the processing of conventional thinned wafers, which not only simplifies the process but is also more conducive to achieving large-scale batch production.
(3) Proposal of a complete sidewall repair solution, which not only reduces surface roughness but also proactively fills defects, improving structural reliability. Addressing the inevitable problems of sidewall roughness or micro-cracks during the processing, the disclosure proposes a complete repair solution including plasma treatment and material filling. This solution is not only passively reducing surface roughness but also proactively filling potential defects, significantly improving the mechanical strength and electrical reliability of the microstructure, which is crucial for subsequent metal filling and component integration.
(4) Integration of on-line inspection technology, achieving real-time quality monitoring and process feedback, ensuring the yield and performance of the final product. The disclosure directly integrates non-destructive inspection technology into the production line, replacing the traditional time-consuming and inefficient off-line sampling inspection. This achieves real-time quality monitoring and process feedback for the product, forming a closed-loop intelligent production model that could instantly intercept defective products, avoid batch scrapping, and maximize the yield and performance of the final product.

Note that the specification relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. A method for manufacturing a semiconductor device, comprising the steps of:
providing at least one substrate; and
performing at least one forming step for forming at least one microstructure on the substrate by utilizing at least one or a combination selected from a group consisting of a laser processing technique, a microwave processing technique, a radio frequency processing technique, an electrical discharge machining technique, a wet chemical processing technique, a mechanical processing technique, a plasma source processing technique, a particle beam processing technique, and a build-up processing technique, wherein the microstructure is at least one or a combination selected from a group consisting of a hole-shaped structure, a line structure, and an optical structure.

2. The method as claimed in claim 1, wherein the forming step utilizes the at least one or the combination selected from the group consisting of the laser processing technique, the microwave processing technique, the radio frequency processing technique, the electrical discharge machining technique, the wet chemical processing technique, the mechanical processing technique, the plasma source processing technique, the particle beam processing technique, and the build-up processing technique to directly form the microstructure on a surface or inside a processing target region of the substrate.

3. The method as claimed in claim 1, wherein the forming step further comprises:
performing a modification step for forming a modified layer on a surface or inside a processing target region of the substrate; and
performing a removal step for removing the modified layer on the substrate, thereby forming the microstructure on the substrate.

4. The method as claimed in claim 3, wherein the modification step utilizes at least one or a plurality selected from the group consisting of the laser processing technique and the particle beam processing technique, and the removal step independently uses or uses a combination of one or a plurality selected from the group consisting of the laser processing technique, the microwave processing technique, the radio frequency processing technique, the electrical discharge machining technique, the wet chemical processing technique, the mechanical processing technique, the particle beam processing technique, and the plasma source processing technique to remove the modified layer to form the microstructure.

5. The method as claimed in claim 1, wherein the laser processing technique uses a pulsed laser.

6. The method as claimed in claim 3, wherein the modification step forms the modified layer on the surface or inside the processing target region of the substrate by a first energy, wherein the modification step causes the first energy to interact with a second energy, thereby generating a forward cycle effect.

7. The method as claimed in claim 3, wherein the removal step wholly or partially removes the modified layer on the substrate by a second energy, wherein the removal step causes the second energy to interact with a first energy, thereby generating a forward cycle effect.

8. The method as claimed in claim 6, wherein the first energy is selected from a group consisting of a laser energy and a particle beam energy, and the second energy is selected from a group consisting of a microwave energy and a radio frequency energy.

9. The method as claimed in claim 4, wherein the modification step uses the laser processing technique to form the modified layer on the surface or inside the processing target region of the substrate, and the removal step uses the electrical discharge machining technique to remove the modified layer, thereby forming a through via that penetrates the substrate or a blind via that does not penetrate the substrate to constitute the microstructure.

10. The method as claimed in claim 3, wherein the modification step uses the laser processing technique to form the modified layer on the surface or inside the processing target region of the substrate, and the removal step uses the wet chemical processing technique, the particle beam processing technique, the plasma source processing technique, and/or the electrical discharge machining technique to remove part or all of the modified layer.

11. The method as claimed in claim 1, wherein the wet chemical processing technique uses chemicals selected from a group consisting of perfluoroalkanes, hydrofluoric acid, hydrochloric acid, sulfuric acid, nitric acid, phosphoric acid, ammonia, ammonium fluoride, potassium hydroxide, ozone, and ozonated water.

12. The method as claimed in claim 11, wherein the wet chemical processing technique is further combined with at least one of the following techniques to improve efficiency: applying ultrasonic vibration; providing bubbles in a liquid and causing the bubbles to generate burst energy; causing the liquid to absorb laser energy to generate an explosive pressure wave; or causing the liquid to absorb laser energy to generate a plasma shock wave.

13. The method as claimed in claim 1, further comprising performing a sidewall repair step on the microstructure formed on the substrate, to reduce a surface roughness of a sidewall of the microstructure or to reduce a chipping phenomenon of the sidewall.

14. The method as claimed in claim 13, wherein the sidewall repair step uses at least one or a plurality selected from a group consisting of the electrical discharge machining technique, the plasma source processing technique, the wet chemical processing technique, an atomic layer etching processing technique, the particle beam processing technique, and a grinding or polishing process to modify or optimize the sidewall of the microstructure.

15. The method as claimed in claim 14, wherein the wet chemical processing technique comprises using ozonated water.

16. The method as claimed in claim 13, wherein the sidewall repair step further comprises performing a filling step, which is providing a repair material to fill a defect on the sidewall of the microstructure.

17. The method as claimed in claim 16, wherein the filling step is performed in combination with a heat source and/or an ultrasonic wave, to assist the repair material in filling the defect on the sidewall of the microstructure.

18. The method as claimed in claim 13, wherein the sidewall repair step is performed in combination with a heat source and/or an ultrasonic wave, to improve the efficiency of repairing the sidewall of the microstructure.

19. The method as claimed in claim 14, wherein the grinding or polishing process uses at least one or a plurality selected from a group consisting of atomic layer etching, providing grinding powder or slurry, and providing a flexible wire or flexible sheet.

20. The method as claimed in claim 13, wherein the sidewall repair step forms an anti-crack bonding layer that at least covers a defect on the sidewall of the microstructure, wherein the anti-crack bonding layer is an insulating, semi-insulating, or conductive material.

21. The method as claimed in claim 13, further comprising performing an inspection procedure for first obtaining a degree of repair needed for the microstructure, and then determining an extent of implementation of the sidewall repair step according to the degree of repair needed for the microstructure.

22. The method as claimed in claim 3, wherein the removal step comprises:
performing the electrical discharge machining technique via a first discharge electrode for applying a first discharge energy onto the modified layer, to form the microstructure; and
performing the electrical discharge machining technique via a second discharge electrode or the first discharge electrode for applying a second discharge energy onto the microstructure, thereby modifying or optimizing the microstructure.

23. The method as claimed in claim 1, wherein the forming step utilizes the electrical discharge machining technique to form the microstructure on a surface or inside a processing target region of the substrate, and the electrical discharge machining technique adjusts a morphology of the microstructure by adjusting discharge parameters of a first discharge electrode.

24. The method as claimed in claim 1, wherein the electrical discharge machining technique applies a first discharge energy onto the substrate via a first discharge electrode, and guides the first discharge electrode to apply the first discharge energy onto the substrate by a magnetic field.

25. The method as claimed in claim 1, wherein the electrical discharge machining technique applies a first discharge energy onto the substrate via a first discharge electrode, and a surface portion of the first discharge electrode is partially covered with a non-conductive material pattern for defining a discharge region, and the electrical discharge machining technique correspondingly adjusts a width or a depth of the microstructure by adjusting a size of the discharge region defined by the non-conductive material pattern or a thickness of the non-conductive material pattern.

26. The method as claimed in claim 25, wherein the non-conductive material pattern is formed on the surface of the first discharge electrode by a nano-imprinting method.

27. The method as claimed in claim 1, wherein the electrical discharge machining technique further comprises applying a suction force to guide a processing fluid through the hole-shaped structure.

28. The method as claimed in claim 27, wherein the processing fluid is at least one selected from a group consisting of kerosene, water, and gas.

29. The method as claimed in claim 1, wherein the electrical discharge machining technique performs an electrochemical discharge machining process on the substrate via an electrolyte.

30. The method as claimed in claim 1, further comprising utilizing the plasma source processing technique to modify or optimize a surface of the substrate or the microstructure formed on the substrate.

31. The method as claimed in claim 30, wherein the plasma source is a remote plasma source (RPS).

32. The method as claimed in claim 1, wherein the forming step further comprises providing a heat source or a cold source to improve the processing efficiency in the forming step.

33. The method as claimed in claim 1, wherein the microstructure is the hole-shaped structure, and in the forming step, the substrate is placed on a stage having a hollow region, and the hollow region of the stage corresponds to a position on the substrate where the hole-shaped structure is formed.

34. The method as claimed in claim 1, wherein the microstructure is the hole-shaped structure, and the hole-shaped structure has at least one of the following features: a diameter ranging from 0.01 μm to 300 μm; an aspect ratio ranging from 100:1 to 1:10; an average sidewall surface roughness of less than 5 μm; and a taper angle greater than 70 degrees.

35. The method as claimed in claim 1, wherein the substrate comprises a material selected from a group consisting of silicon dioxide, silicon, gallium arsenide, indium phosphide, silicon carbide, gallium nitride, and gallium oxide, and an external shape of the substrate is selected from a group consisting of a cylinder, a cuboid, a multifaceted shape, and an irregular shape.

36. The method as claimed in claim 1, wherein the microstructure is the hole-shaped structure, and the method further comprises, after the hole-shaped structure is formed, lining the sidewall of the hole-shaped structure or filling the inside of the hole-shaped structure with a metal material.

37. The method as claimed in claim 1, wherein the hole-shaped structure is selected from a group consisting of a through via that penetrates the substrate and a blind via that does not penetrate the substrate, the optical structure is selected from a group consisting of a grating structure, a waveguide structure, and a curved surface structure, and the line structure is a Redistribution Layer (RDL), an interconnect structure, or a local interconnect structure.

38. The method as claimed in claim 1, wherein the substrate is a block structure that has not undergone a slicing process.

39. The method as claimed in claim 38, wherein before performing the forming step, the method further comprises first fixing the block structure with a fixture, and after performing the forming step, performing the slicing process on the block structure.

40. The method as claimed in claim 38, wherein before performing the forming step, the method further comprises first adhering the block structure to a carrier with an adhesive layer, and after performing the forming step, performing the slicing process on the block structure, and the adhesive layer is a conductive adhesive layer or a non-conductive adhesive layer.

41. The method as claimed in claim 40, wherein after performing the forming step, the method further comprises a separation step for separating the sliced substrate from the carrier, and the separation step is selected from a group consisting of: immersing in hot water at a temperature higher than 80 degrees Celsius, an acid solution with a pH value less than 7, or an alkaline solution with a pH value greater than 7; providing a heat source; and providing a light source to degrade the adhesive properties of the adhesive layer.

42. The method as claimed in claim 41, wherein the separation step further comprises applying an ultrasonic wave in combination.

43. The method as claimed in claim 1, wherein before and/or after performing the forming step, the method further comprises performing a planarization treatment process on a surface of the substrate to reduce profile variations and/or reduce roughness.

44. The method as claimed in claim 1, wherein the substrate is a wafer that has undergone a slicing process.

45. The method as claimed in claim 1, further comprising performing a bonding step, which is electrically or physically connecting the substrate formed with the microstructure to at least one selected from a group consisting of a carrier board, a computing unit, a memory unit, and an input/output unit.

46. The method as claimed in claim 45, wherein the bonding step is performed through at least one method selected from a group consisting of a bump, a micro bump, a thermal compression bonding (TCB) technique, a room temperature bonding technique, and a hybrid bonding technique.

47. The method as claimed in claim 45, wherein before the bonding step, the method further comprises performing a planarization treatment process on a surface of the substrate to be bonded, to reduce profile variations and/or reduce roughness.

48. The method as claimed in claim 43, wherein the planarization treatment process uses one or a plurality selected from a group consisting of a dry etching processing technique, a wet etching processing technique, a chemical mechanical polishing (CMP) processing technique, the laser processing technique, the plasma source processing technique, the electrical discharge machining technique, and the particle beam processing technique.

49. The method as claimed in claim 48, wherein the plasma source of the plasma source processing technique is selected from one of a group consisting of a remote plasma source (RPS), an inductively coupled plasma (ICP), a capacitively coupled plasma (CCP), and a surface wave coupled plasma (SWCP).

50. The method as claimed in claim 43, wherein the planarization treatment process is further combined with at least one element selected from a group consisting of a heat source, a cold source, and an ultrasonic wave to improve processing efficiency.

51. The method as claimed in claim 45, wherein the carrier board is selected from a group consisting of an Ajinomoto Build-up Film (ABF) substrate, a bismaleimide-triazine (BT) substrate, a Molded Interconnect Substrate (MIS), and a Printed Circuit Board (PCB).

52. The method as claimed in claim 45, wherein a surface of the substrate to be bonded comprises a pattern, the pattern is formed of a material selected from a group consisting of a conductive material, a semi-insulating material, and an insulating material, and the pattern is periodically or non-periodically distributed on the surface to be bonded.

53. The method as claimed in claim 1, wherein the substrate is provided by the following steps:
providing a bonded structure, the bonded structure comprising a first wafer and a second wafer bonded to each other; and
separating the bonded structure using a cutting technique to obtain the substrate.

54. The method as claimed in claim 53, wherein the first wafer is a polycrystalline silicon carbide wafer, and the second wafer is a silicon carbide wafer on which a partial process has been completed.

55. The method as claimed in claim 53, wherein the first wafer and the second wafer comprise materials selected from a group consisting of silicon, silicon dioxide, silicon carbide, lithium tantalate, lithium niobate, indium phosphide, gallium nitride, gallium oxide, polyimide, diamond, and metal.

56. The method as claimed in claim 53, wherein the cutting technique is selected from a group consisting of laser processing, slurry wire sawing, diamond wire sawing, and wire electrical discharge machining (WEDM).

57. The method as claimed in claim 53, wherein after separating the bonded structure using the cutting technique, the method further comprises performing at least one selected from a group consisting of a grinding process, a lapping process, and a polishing process on the obtained substrate.

58. The method as claimed in claim 1, wherein the substrate is a lens, and the optical structure of the microstructure comprises a structure selected from a group consisting of a waveguide structure, a curved surface structure, and a grating structure.

59. The method as claimed in claim 58, wherein the forming step utilizes the electrical discharge machining technique to form the grating structure on the substrate, and further comprises applying a magnetic field during the electrical discharge machining technique to control a profile of the grating structure to be vertical or slanted.

60. The method as claimed in claim 58, further comprising performing a grinding or polishing process on a processing target surface of the lens, the waveguide structure, the curved surface structure, or the grating structure, wherein the grinding or polishing process performs a conformal processing on the processing target surface with an energy, thereby obtaining a predetermined processing morphology.

61. The method as claimed in claim 58, wherein the lens has a function selected from a group consisting of turning light, reflecting light, refracting light, and diffracting light.

62. The method as claimed in claim 58, wherein the lens is made of an N-type semiconductor, a semi-insulating semiconductor, or a material with a refractive index greater than 1.5.

63. The method as claimed in claim 58, wherein the grating structure or the curved surface structure is a one-dimensional, two-dimensional, or three-dimensional structure.

64. The method as claimed in claim 58, wherein the material of the waveguide structure is the same as or different from the material of the lens.

65. The method as claimed in claim 1, wherein the forming step is the build-up processing technique, and the build-up processing technique is selected from a group consisting of an adhesion process, a coating process, a film formation process, a plating process, an electroplating process, an atomic layer deposition process, and an additive manufacturing process.

66. The method as claimed in claim 1, wherein before or after performing the forming step, the method further comprises performing an inspection procedure on the substrate or the microstructure on the substrate, wherein the inspection procedure is at least one selected from a group consisting of material characteristic inspection, external feature inspection, and optical characteristic inspection.

67. The method as claimed in claim 66, wherein the external feature inspection is used to measure a size, a curvature, a surface roughness, a scratch, or a tilt angle of the substrate or the microstructure on the substrate.

68. The method as claimed in claim 66, wherein the optical characteristic inspection uses a light source to perform measurement and analysis of an optical characteristic at the same or different wavelengths, the optical characteristic being at least one selected from a group consisting of refractive index, transmittance, reflectance, extinction coefficient, spectral efficiency, diffraction intensity, diffraction efficiency, dispersion, light diffusion angle, light leakage rate, final field of view, information at different light exit angles, light intensity uniformity at different light exit angles, and aberration.

69. The method as claimed in claim 68, wherein the light source is a point light source, a line light source, an area light source, a polarized light source, a laser source, an image source, a single wavelength source, a multi-wavelength source, a standard test source, a standard test image source, or any combination thereof.

70. The method as claimed in claim 66, wherein the inspection procedure is performed using at least one instrument selected from a group consisting of an atomic force microscope, a white light interferometer, an ellipsometer, a near-field optical microscope, a scanning acoustic microscope, an X-ray scanning technique, and an electron microscope.

71. The method as claimed in claim 66, wherein the inspection procedure is integrated with a manufacturing system for on-line inspection.

72. The method as claimed in claim 66, wherein the inspection procedure is a contact-type inspection, a non-contact-type inspection, a destructive inspection, or a non-destructive inspection.

73. The method as claimed in claim 66, wherein the inspection procedure comprises: providing an energy source to interact with the substrate or the microstructure, and performing the inspection based on a change in a feedback signal or a difference in an input and output performance, wherein the energy source is selected from a group consisting of a light source, a force source, and a vibration source.

74. The method as claimed in claim 66, wherein the material characteristic inspection comprises inspecting a doping concentration, a crystal defect, a crystal lattice structure, or a crystal orientation of the substrate or the microstructure.

75. The method as claimed in claim 70, wherein when the inspection procedure utilizes the X-ray scanning technique, the inspection procedure is performed by analyzing a change in an absorption information or a diffraction information of the substrate or the microstructure.

76. The method as claimed in claim 1, wherein the forming step forms the hole-shaped structure of the microstructure by the mechanical processing technique using a cutting fluid, and the cutting fluid simultaneously protects a sidewall of the hole-shaped structure or forms a protective layer on the sidewall during the formation of the hole-shaped structure.

77. The method as claimed in claim 1, wherein after the forming step forms a Redistribution Layer (RDL) of the line structure of the microstructure, the method further comprises treating the Redistribution Layer (RDL) with ozonated water, and/or after the forming step forms the hole-shaped structure of the microstructure, the method further comprises treating the hole-shaped structure with a remote plasma source.

78. The method as claimed in claim 1, wherein after the forming step forms the hole-shaped structure of the microstructure, the method further comprises treating the hole-shaped structure with ozonated water, the particle beam processing technique, or an anti-crack bonding layer according to a degree of repair needed for the hole-shaped structure.

79. The method as claimed in claim 1, wherein after providing the substrate and before performing the forming step, the method further comprises performing an inspection procedure for inspecting a quality of the substrate, the quantity of the substrate being one or a plurality.

80. The method as claimed in claim 79, wherein the quantity of the substrate is the plurality, and the inspection procedure comprises the steps of:
stacking the plurality of substrates;
causing an X-ray to interact with the plurality of substrates through transmission and/or reflection, thereby forming a plurality of diffraction information that can be received by a sensing element; and
analyzing the plurality of diffraction information, thereby obtaining the quality of each of the plurality of substrates.

81. A method for inspecting a semiconductor device, comprising the steps of:
providing a substrate, the substrate being formed with a microstructure, wherein the microstructure is at least one or a combination selected from a group consisting of a hole-shaped structure, a line structure, and an optical structure, and a sidewall of the microstructure is lined with or filled inside with a metal material; and
performing an inspection procedure for utilizing an inspection technique based on electrical and magnetic properties and their interaction to inspect the metal material on the substrate, thereby obtaining an inspection result having characteristic data of the metal material.

82. The method as claimed in claim 81, wherein the inspection technique is an eddy current detection technique.

83. The method as claimed in claim 81, wherein the characteristic data comprises at least one of electrical properties, magnetic properties, resistance characteristics, structural density, or structural defects of the metal material.

84. The method as claimed in claim 81, further comprising performing a transmission step for instantly transmitting the inspection result to a conveying equipment or a process equipment, so that the conveying equipment or the process equipment performs a corresponding action based on the received inspection result.

85. The method as claimed in claim 84, wherein the inspection procedure is performed using an inspection device integrated into the conveying equipment or the process equipment.

86. The method as claimed in claim 84, wherein the conveying equipment is an Equipment Front End Module (EFEM).

87. The method as claimed in claim 84, wherein the process equipment is a vapor deposition equipment, a sputtering equipment, a chemical vapor deposition equipment, a physical vapor deposition equipment, an atomic layer deposition equipment, a washing equipment, or a cleaning equipment.

88. A semiconductor device formed by the method of claim 1.
